(19) United States
(12) Patent Application Publication
(10) Pub. No.: US 2024/0268199 A1
(43) Pub. Date: Aug. 8, 2024

(54) DISPLAY PANEL AND METHOD OF MANUFACTURING THE SAME

(71) Applicant: Samsung Display Co., Ltd., Yongin-si (KR)

(72) Inventor: HYUNEOK SHIN, Yongin-si (KR)

(21) Appl. No.: 18/378,654

(22) Filed: Oct. 11, 2023

(30) Foreign Application Priority Data
Feb. 8, 2023 (KR) 10-2023-0017010

(51) Int. Cl. H10K 59/80; G02B 27/01; H10K 59/12; H10K 59/122; H10K 59/32; H10K 59/38; H10K 71/20; H10K 71/60

(52) U.S. Cl. CPC H10K 59/879; G02B 27/0172; H10K 59/1201; H10K 59/122; H10K 59/32; H10K 59/38; H10K 59/80517; H10K 71/233; H10K 71/60; H10K 2102/101; H10K 2102/351

(57) ABSTRACT

Disclosed is a method of manufacturing a display panel. The method includes forming a lower layer on a base layer, forming a preliminary anode including a first initial layer and a second initial layer on the lower layer, patterning the preliminary anode so as to form an anode including a first layer and a second layer, forming an emission part, and forming a cathode. The patterning of the preliminary anode includes forming a photoresist layer, etching the first and second initial layers to form the first layer and the second layer, removing the photoresist layer, and first cleaning. At least a part of the lower layer exposed from the anode is removed during the removing of the photoresist layer or the first cleaning.

### CROSS-REFERENCE TO RELATED APPLICATIONS

This U.S. non-provisional patent application claims priority under 35 U.S.C. § 119 of Korean Patent Application No. 10-2023-0017010, filed on Feb. 8, 2023, the entire contents of which are hereby incorporated by reference.

### BACKGROUND

The present disclosure relates to a display panel and a method for manufacturing the same, and more particularly, to a display panel that makes it easy to achieve high resolution and a method for manufacturing the same.

Multimedia display apparatuses such as televisions, mobile phones, tablet PCs, computers, navigation devices, game machines, and the like may be provided with a display panel for displaying an image. The display panel may include an array of pixels for displaying an image, and each of the pixels may include a pixel element connected to a light-emitting element that generates light. Current display panels often need to display high resolution images, which may require precision or refinement of patterns or structures in the display panels.

### SUMMARY

The present disclosure describes examples of display panels that may achieve high resolution by reducing process errors at anodes of light-emitting elements. The present disclosure also describes examples of methods for manufacturing display panels.

An embodiment disclosed herein provides a method of manufacturing a display panel, the method including: forming a lower layer on a base layer; forming a preliminary anode including a first initial layer and a second initial layer sequentially laminated on the lower layer; patterning the preliminary anode so as to form an anode including a first layer and a second layer; forming an emission part on the anode; and forming a cathode on the emission part. In an embodiment, the patterning of the preliminary anode may include: forming a photoresist layer on the second initial layer; etching the first and second initial layers so as to form the first layer and the second layer respectively from the first initial layer and the second initial layer; removing the photoresist layer; and first cleaning, wherein the lower layer may include a first portion overlapping the anode and a second portion extending by the anode, and at least a part of the second portion may be removed during at least one of the removing of the photoresist layer or the first cleaning.

In an embodiment, a strip solution may be used in the removing of the photoresist layer, and the lower layer may be soluble in the strip solution.

In an embodiment, a first cleaning solution may be used in the first cleaning, and the lower layer may be soluble in the first cleaning solution.

In an embodiment, the first cleaning solution may include deionized (DI) water.

In an embodiment, the first cleaning may be performed for about 30 seconds to about 120 seconds.

In an embodiment, the lower layer may include any one of tungsten oxide and molybdenum titanium oxide, the first initial layer may include metal, and the second initial layer may include a transparent conductive oxide.

In an embodiment, a thickness of the lower layer may be about 10 nanometers or less.

In an embodiment, the second portion may be entirely removed during the removing of the photoresist layer or the first cleaning, thus forming a lower pattern from the lower layer, and the lower pattern may correspond to the first portion.

In an embodiment, a part of the second portion may be removed during the removing of the photoresist layer, thus forming a third portion that is thinner than the second portion, the third portion may be entirely removed during the first cleaning, thus forming a lower pattern from the lower layer, and the lower pattern may correspond to the first portion.

In an embodiment, the method may further include, before the forming of the emission part after the patterning of the preliminary anode: second cleaning; and forming a pixel defining layer in which a pixel opening that exposes at least a portion of the anode is defined. In an embodiment, a part of the second portion may be removed during the patterning of the preliminary anode, thus forming a fourth portion that is thinner than the second portion, the fourth portion may be entirely removed during the second cleaning, thus forming a lower pattern from the lower layer, and the lower pattern may correspond to the first portion.

In an embodiment, a width of the pixel opening in one direction may be about 2 micrometers to about 8 micrometers.

In an embodiment, the base layer may include a silicon wafer.

In an embodiment, the method may further include, after the forming of the cathode: forming an encapsulation layer on the cathode; and forming, on the encapsulation layer, a color filter layer including a first color filter overlapping the first anode and a second color filter overlapping the second anode.

In an embodiment, the method may further include forming a lens layer including a first mounted lens arranged on the first color filter and a second mounted lens arranged on the second color filter.

In an embodiment disclosed herein, a display panel includes: a base layer including a silicon wafer; a first lower pattern on the base layer; a first anode including a first layer and a second layer sequentially laminated on the first lower pattern; a pixel defining layer arranged on the base layer and having defined therein a first pixel opening that exposes at least a portion of the first anode; an emission part on the first anode; and a cathode on the emission part, wherein the first lower pattern includes a metal oxide, and a thickness of the first lower pattern is about 10 nanometers or less.

In an embodiment, a width of the first pixel opening in one direction may be about 2 micrometers to about 8 micrometers.

In an embodiment, the first lower pattern may include any one of tungsten oxide and molybdenum titanium oxide.

In an embodiment, the display panel may further include: a second lower pattern arranged on the base layer and spaced apart from the first lower pattern; a second anode arranged on the second lower pattern and spaced apart from the first anode; a color filter layer arranged on the cathode and including a first color filter overlapping the first anode and a second color filter overlapping the second anode; and a planarization layer on the color filter layer.

In an embodiment, the emission part may include multiple light-emitting stacks and at least one charge generation layer between the light-emitting stacks, and may be commonly arranged on the first anode and the second anode.

In an embodiment, the display panel may further include a lens layer arranged between the color filter layer and the planarization layer and including a first mounted lens overlapping the first anode and a second mounted lens overlapping the second anode.

### BRIEF DESCRIPTION OF THE FIGURES

The accompanying drawings are included to provide a further understanding of the present disclosure and are incorporated in and constitute a part of this specification. The drawings, together with the description, serve to illustrate and explain principles of some examples in accordance with the present disclosure.

FIG. 1A is a perspective view of an electronic device according to an example of a present disclosure.

FIG. 1B is an exploded perspective view of an electronic device according to an example of a present disclosure.

FIGS. 1C and 1D are cross-sectional views schematically illustrating a display module according to an example of a present disclosure.

FIG. 2A is a perspective view of an electronic device according to an example of a present disclosure.

FIG. 2B is an exploded perspective view of an electronic device according to an example of a present disclosure.

FIG. 3 is an enlarged plan view illustrating a partial region of a display panel according to an example of a present disclosure.

FIG. 4 is a cross-sectional view of the display panel of FIG. 3 taken along line I-I′ of FIG. 3.

FIGS. 5A and 5B are enlarged cross-sectional views of portions of a light-emitting element according to an example of a present disclosure.

FIG. 6 is a cross-sectional view of the display panel of FIG. 3 taken along line I-I′ of FIG. 3.

FIGS. 7A, 7B, 7C, 7D, 7E, 7F, 7G, 7H, and 7I are cross-sectional views illustrating some structures created during a display panel manufacturing method according to an example of a present disclosure.

FIG. 8 is a cross-sectional view illustrating a structure created during a display panel manufacturing method according to an example of a present disclosure.

FIGS. 9A and 9B are cross-sectional views illustrating structures created during a display panel manufacturing method according to an example of a present disclosure.

### DETAILED DESCRIPTION

It will be understood that when an element (or a region, layer, portion, or the like) is referred to as being “on”, “connected to”, or “coupled to” another element, it can be directly on or directly connected/coupled to the other element, or a third element may be present therebetween.

The same reference numerals used in different drawings refer to the same or similar elements. In the drawings, the thicknesses, ratios, and dimensions of elements may be exaggerated for clarity of illustration. As used herein, the term “and/or” includes any combinations that can be defined by associated elements.

The terms “first”, “second” and the like may be used for describing various elements, but the elements should not be construed as being limited by the terms. Such terms are only used for distinguishing one element from other elements. For example, a first element could be termed a second element and vice versa. Terms of a singular form may include plural forms unless otherwise specified.

Furthermore, the terms “under”, “lower side”, “on”, “upper side”, and like are used to describe association relationships among elements illustrated in the drawings. The terms, which are relative concepts, are used on the basis of directions illustrated in the drawings.

It will be further understood that the terms “include”, “including”, “has”, “having”, and the like, when used in this specification, specify the presence of stated features, numbers, steps, operations, elements, components, or combinations thereof, but do not preclude the presence or addition of one or more other features, numbers, steps, operations, elements, components, or combinations thereof.

All of the terms used herein (including technical and scientific terms) have the same meanings as understood by those skilled in the art, unless otherwise defined. Terms in common usage such as those defined in commonly used dictionaries should be interpreted to contextually match the lexical meanings in the relevant art, and should not be interpreted in an idealized or overly formal sense unless otherwise defined explicitly.

Hereinafter, examples in accordance with the present disclosure will be described in detail with reference to the accompanying drawings.

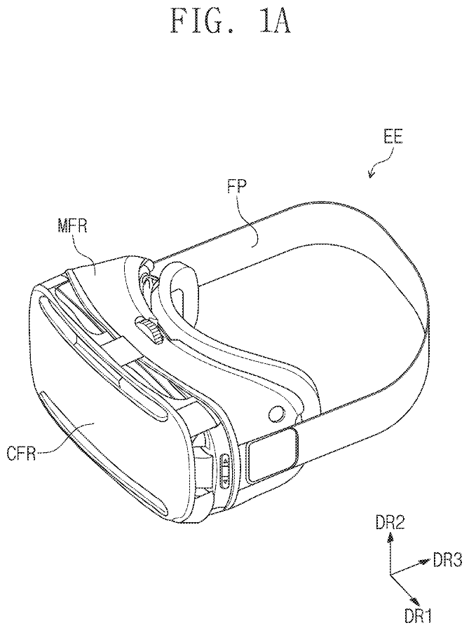

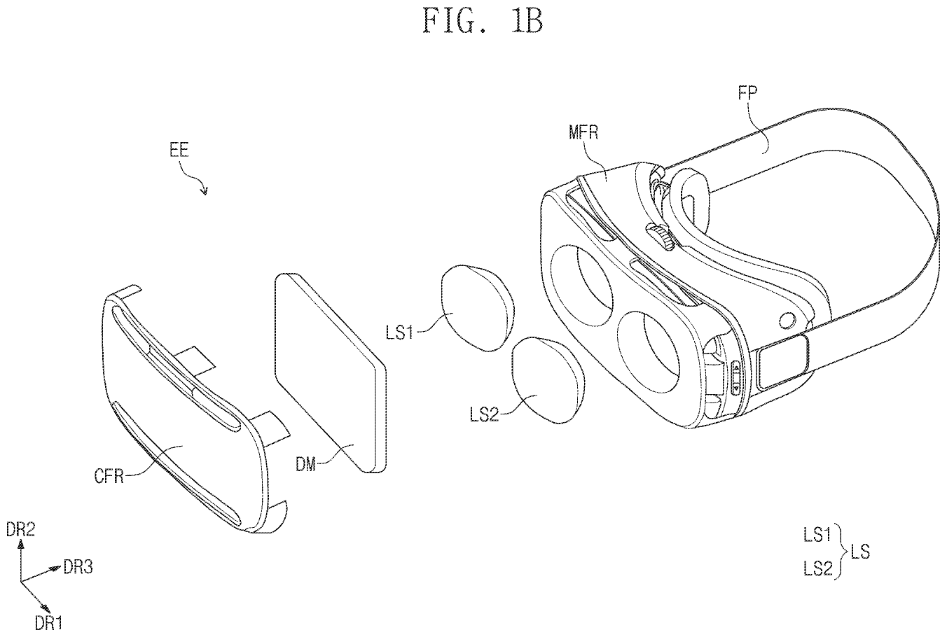

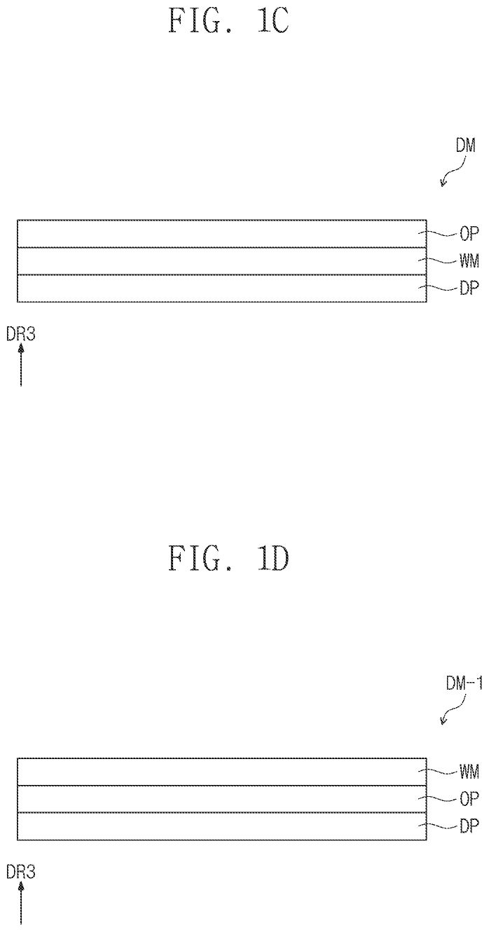

FIG. 1A is a perspective view of an electronic device EE according to an embodiment of the present disclosure. FIG. 1B is an exploded perspective view of electronic device EE of FIG. 1A and shows a display module DM of electronic device EE. FIGS. 1C and 1D are cross-sectional views schematically illustrating alternative structures of display module DM. The electronic device EE may be a device that is activated in response to an electric signal. For example, the electronic device EE may be a television, monitor, outdoor billboard, game machine, personal computer, laptop computer, mobile phone, tablet PC, navigation device, and wearable device, but an embodiment is not limited thereto.

FIGS. 1A and 1B illustrate a head mounted display (HMD) as an example of the electronic device EE. The head mounted display may be an electronic device that is worn on a head of a user and provides to the user a screen on which an image or video is displayed. The head mounted display may be a see-through type device that displays or provides to the user an augmented reality (AR) based on actual external objects or a see-closed type device that displays or provides to the user a virtual reality (VR) independent of external objects.

Referring to FIGS. 1A and 1B, the electronic device EE may include display module DM and a lens part LS facing the display module DM. Furthermore, the electronic device EE may include a main frame MFR, a cover frame CFR, and a fixing part FP.

The main frame MFR may be a part that is worn on a face of the user. The main frame MFR may have a shape corresponding to the shape of the head (face) of the user. For example, a length of the fixing part FP may be adjusted according to a head circumference of the user. The fixing part FP is a structure for the user to easily wear the main frame MFR, and may include a strap, band, and the like. However, an embodiment is not limited thereto, and the main fixing part FP may have various forms such as a helmet, eyeglass temples, and the like coupled to the main frame MFR.

The main frame MFR may be coupled to the cover frame CFR to provide an accommodation space for mounting the lens part LS and the display module DM.

The lens part LS may be arranged between the display module DM and the user. The lens part LS may allow light emitted from the display module DM to pass through, and may provide the light to the user. For example, the lens part LS may include various types of lenses such as multi-channel lenses, convex lenses, concave lenses, spherical lenses, aspheric lenses, single lenses, compound lenses, standard lenses, narrow-angle lenses, wide-angle lenses, fixed-focal lenses, varifocal lenses, etc.

The lens part LS may include a first lens LS1 and a second lens LS2. The first lens LS1 and the second lens LS2 may be arranged in correspondence with positions of a left eye and right eye of the user. The first lens LS1 and the second lens LS2 may be accommodated in the main frame MFR.

The display module DM may be fixed to the main frame MFR or detachable. The display module DM may provide an image to the user, wherein the image may include not only a moving image but also a still image. The display module DM is described in more detail below.

The cover frame CFR may be arranged predominantly on one side of the display module DM to protect the display module DM. The cover frame CFR may be spaced apart from the lens part LS with the display module DM therebetween.

Although FIGS. 1A and 1B and the following figures illustrate first to third directions DR1 to DR3, the directions DR1 to DR3 described herein are relative, and thus may be changed. Furthermore, the directions indicated by the first to third directions DR1 to DR3 may be referred to as first to third directions, and the same reference signs may be used. Herein, the first direction DR1 and the second direction DR2 may be perpendicular to each other, and the third direction DR3 may be a normal direction to the plane defined by the first direction DR1 and the second direction DR2.

A thickness direction of the electronic device EE may be parallel with the third direction DR3 that is the normal direction to the plane defined by the first direction DR1 and the second direction DR2. In the present disclosure, front surfaces (or top surfaces) and rear surfaces (or bottom surfaces) of members constituting the electronic device EE may be defined based on the third direction DR3. In the present disclosure, the term “in a plan view” represents a surface that is parallel with the plane defined by the first direction DR1 and the second direction DR2, and the term “in a cross-sectional view” represents a surface that is parallel with the third direction DR3.

Referring to FIGS. 1C and 1D, display modules DM and DM-1 according to the present embodiment may include a display panel DP, a window member WM, and an optical member OP.

The display panel DP may be a component that substantially generates an image. The image generated by the display panel DP may be externally viewed by the user.

The display panel DP may be an emissive display panel, but is not particularly limited. For example, the display panel DP may be an organic light-emitting display panel or an inorganic light-emitting display panel. The organic light-emitting display panel may be a display panel in which an emission layer includes an organic light-emitting material. The inorganic light-emitting display panel may be a display panel in which an emission layer includes a quantum dot, quantum rod, or micro LED. The display panel DP is described as an organic light-emitting display panel below.

The window member WM may be arranged on the display panel DP as shown in FIG. 1C. The window member WM may include an optically clear insulating material. For example, the window member WM may include glass or plastic. The window member WM may have a multi-layer structure or single-layer structure. For example, the window member WM may include a plurality of plastic films bonded by an adhesive or may include a glass substrate and a plastic film bonded by an adhesive.

The optical member OP may be arranged on the display panel DP as shown in FIG. 1C. The optical member OP may be a polarization member, a color filter, or a wavelength filter. The optical member OP may improve display characteristics of the display panel DP by controlling light incident on or transmitted through the optical member OP.

As illustrated in FIG. 1C, according to the display module DM of an embodiment, the optical member OP may be arranged on the window member WM. Meanwhile, as illustrated in FIG. 1D, according to the display module DM-1 of an embodiment, the optical member OP may be arranged between the window member WM and the display panel DP. Alternatively, according to a display module of an embodiment, the optical member may not be provided in a display module in accordance with an embodiment.

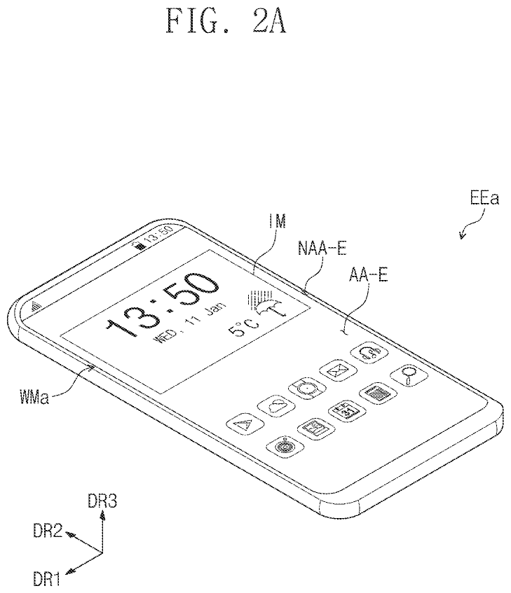

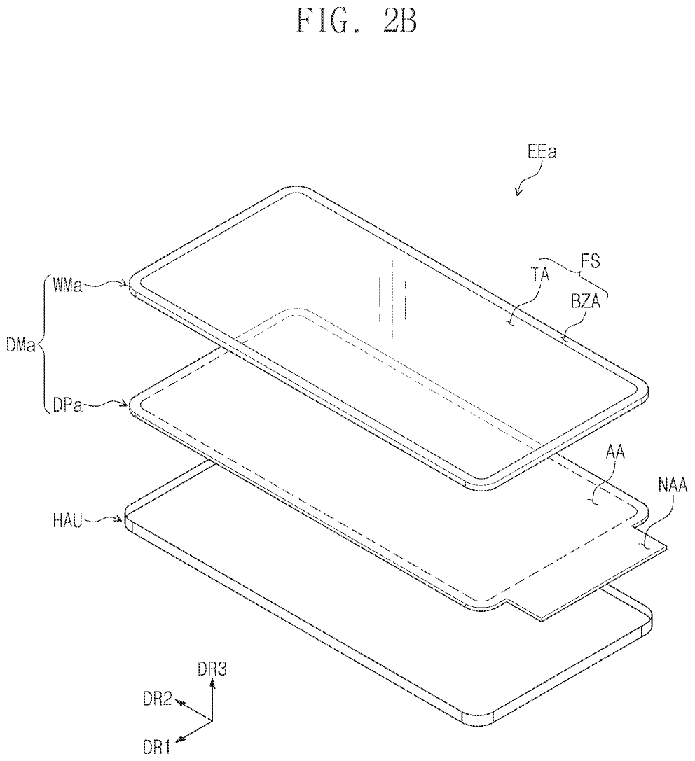

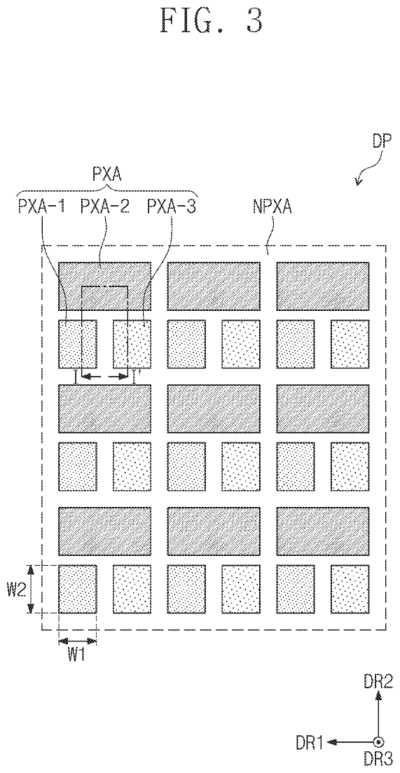

FIG. 2A is a perspective view of an electronic device according to an embodiment of the present disclosure. FIG. 2B is an exploded perspective view of an electronic device according to an embodiment of the present disclosure.

FIGS. 2A and 2B illustrate a mobile phone as an example of an electronic device EEa according to an embodiment of the present disclosure.

The electronic device EEa may display an image IM through an active region AA-E. The active region AA-E may have a primary surface or face parallel to the plane defined by the first direction DR1 and the second direction DR2. A peripheral region NAA-E is adjacent to the active region AA-E. The peripheral region NAA-E may surround the active region AA-E. However, the peripheral region NAA-E may be arranged adjacent to only one side of the active region AA-E or may not be provided.

The electronic device EEa according to the present embodiment may include a housing HAU and a display module DMa as shown in FIG. 2B. The display module DMa according to the present embodiment may include a display panel DPa and a window member WMa.

The window member WMa may cover an entire outer side of the display module DMa. The window member WMa may include a transmissive region TA and a bezel region BZA. A front surface of the window member WMa, including the transmissive region TA and the bezel region BZA, may correspond to a front surface of the electronic device EEa. The transmissive region TA may correspond to the active region AA-E of the electronic device EEa illustrated in FIG. 2A, and the bezel region BZA may correspond to the peripheral region NAA-E of the electronic device EEa illustrated in FIG. 2A.

The transmissive region TA may be an optically clear region. The bezel region BZA may have a relatively low light transmittance compared to the transmissive region TA. The bezel region BZA may have a predetermined color. The bezel region BZA may be adjacent to and surround the transmissive region TA. However, the bezel region BZA may be arranged adjacent to only one side of the transmissive region TA or may be partially omitted.

The display panel DPa may include an active region AA and a peripheral region NAA. The active region AA may be a region which is activated in response to an electric signal. In the present embodiment, the active region AA may be a region in which the image IM (see FIG. 2A) is displayed. The active region AA of the display panel DPa may correspond to the active region AA-E of the electronic device EEa illustrated in FIG. 2A, and the peripheral region NAA of the display panel DPa may correspond to the peripheral region NAA-E of the electronic device EEa illustrated in FIG. 2A. The transmissive region TA may overlap at least a portion of the active region AA. The peripheral region NAA may be a region covered with the bezel region BZA.

Although not illustrated, an input sensing unit may be provided on the display panel DPa. The input sensing unit may detect an external input applied externally. The external input may be a user's input. The user's input may include various types of external inputs such as a part of a user's body, light, heat, pen, or pressure. The input sensing unit may be directly arranged on the display panel DPa or may be coupled to the display panel DPa through a separate adhesive member.

In the present disclosure, when an element (or a region, layer, portion, or the like) is referred to as being “directly arranged” on another element, a third element is not between the element and the other element. That is, when an element is referred to as being “directly arranged” on another element, the element “contacts” the other element.

The housing HAU may accommodate the display panel DPa, etc. The housing HAU may be coupled to the window member WMa.

The above descriptions of the active region AA-E and peripheral region NAA-E of the electronic device EEa, the transmissive region TA and bezel region BZA of the window member WMa, and the active region AA and peripheral region NAA of the display panel DPa, provided with reference to FIGS. 2A and 2B, may also be applied to the electronic device EE, the window member WM, and the display panel DP described above with reference to FIGS. 1A to 1D.

FIG. 3 is a plan view illustrating a region of a display panel according to an embodiment of the present disclosure. FIG. 3 is an enlarged view of a portion of an active region of a display panel DP. Hereinafter, the descriptions of the display panel DP of FIG. 3 may also be applied to the display panels DP and DPa included in the electronic devices EE and EEa described above with reference to FIGS. 1A to 2B.

Referring to FIG. 3, the display panel DP may include a pixel region PXA and a non-pixel region NPXA. The non-pixel region NPXA may surround the pixel region PXA. The pixel region PXA may be one of many similar or identical pixel regions in a pixel array. The pixel region PXA may include a first pixel region PXA-1, a second pixel region PXA-2, and a third pixel region PXA-3. The first pixel region PXA-1, the second pixel region PXA-2, and the third pixel region PXA-3 each of which may emit light of a different wavelength region. The first pixel region PXA-1 may emit first light, and the second pixel region PXA-2 may emit second light different from the first light. The third pixel region PXA-3 may emit third light different from the first light and second light. For example, the first light may be red light, the second light may be blue light, and the third light may be green light. However, color of each of the first to third light is not limited to one embodiment.

In the present embodiment, the first pixel regions PXA-1 and the third pixel regions PXA-3 may be alternately arranged in one row (first row) along the first direction DR1. The second pixel regions PXA-2 may be arranged in another row (second row) along the first direction DR1. Each of the second pixel regions PXA-2 may be spaced apart in the second direction DR2 from the first pixel region PXA-1 and the third pixel region PXA-3 which are adjacent to each other. The first row and the second row may be alternately arranged along the second direction DR2. However, this is merely illustrative, and arrangement of the first to third pixel regions PXA-1 to PXA-3 is not limited thereto.

An area size of the second pixel region PXA-2 may be larger than an area size of each of the first and third pixel regions PXA-1 and PXA-3. The first to third pixel regions PXA-1 to PXA-3 may alternatively have the same area size, or the area size of the third pixel region PXA-3 may be larger than the area size of the first pixel region PXA-1. However, these examples are merely illustrative, and the area sizes of the first to third pixel regions PXA-1 to PXA-3 are not limited thereto.

The first to third pixel regions PXA-1 to PXA-3 each may have a quadrilateral shape in a plan view. However, this is merely illustrative, and the first to third pixel regions PXA-1 to PXA-3 may have various shapes in a plan view, such as a polygonal shape, circular shape, and elliptical shape.

Meanwhile, the arrangement, relative size, and shape of the first to third pixel regions PXA-1 to PXA-3 of the display panel DP of an embodiment of the present disclosure may be variously selected according to color of emitted light, or a size or configuration of the display panel DP, and are not limited to the embodiment illustrated in FIG. 3.

In an embodiment of the present disclosure, a width W1 of each of the pixel regions PXA-1 to PXA-3 in the first direction DR1 may be about 2 micrometers to about 8 micrometers. Furthermore, a width W2 of each of the pixel regions PXA-1 to PXA-3 in the second direction DR2 may be about 2 micrometers to about 8 micrometers. When each of the pixel regions PXA-1 to PXA-3 have a width measured in micrometers, e.g., less than about 10 micrometers, the display panel DP suitable for high resolution may be provided.

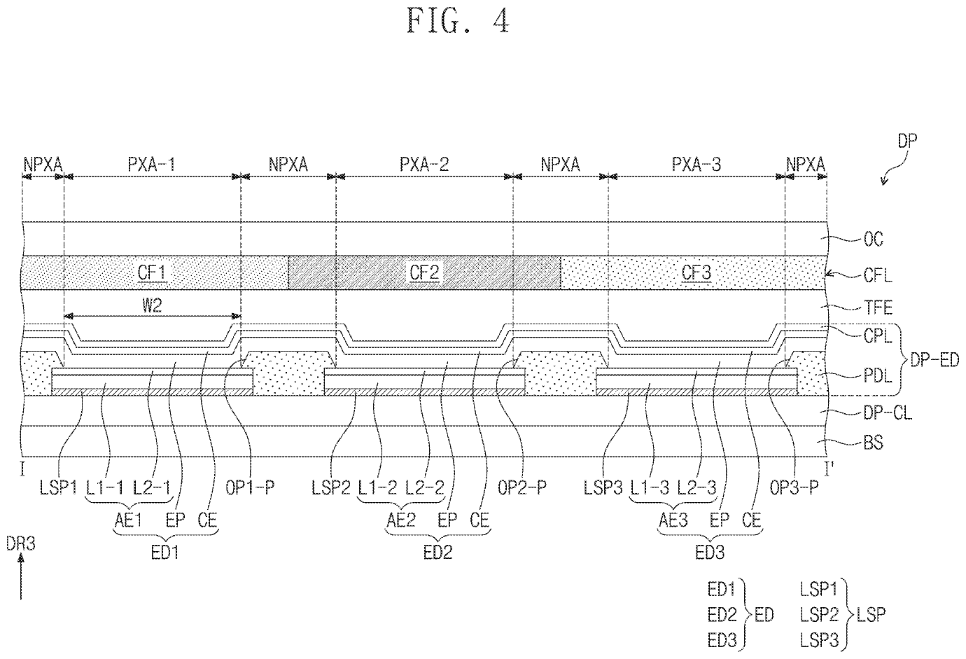

FIG. 4 is a cross-sectional view of the display panel of FIG. 3 taken along line I-I′ of FIG. 3.

Referring to FIG. 4, the display panel DP may include a base layer BS, a circuit layer DP-CL arranged on the base layer BS, a display layer DP-ED arranged on the circuit layer DP-CL, and an encapsulation layer TFE arranged on the display layer DP-ED. Furthermore, the display panel DP may further include a color filter layer CFL and planarization layer OC on the encapsulation layer TFE.

The base layer BS may be a member that provides a base surface on which the circuit layer DP-CL is arranged. The base layer BS may be a rigid substrate or a flexible substrate that is bendable, foldable, or rollable. According to an embodiment, the base layer BS may be a glass substrate, a metal substrate, a polymer substrate, or the like. Alternatively, according to an embodiment, the base layer BS may be a silicon wafer. However, an embodiment is not limited thereto, and the base layer BS may be an inorganic layer, an organic layer, or a composite material layer, and may include not only a single-layer structure but also a multi-layer structure.

The circuit layer DP-CL may be arranged on the base layer BS. The circuit layer DP-CL may include an insulating layer, a semiconductor pattern, a conductive pattern, a signal line, and the like. An insulating layer, a semiconductor layer, and a conductive layer may be formed on the base layer BS through coating, deposition, or the like, and thereafter, the insulating layer, the semiconductor layer, and the conductive layer may be selectively patterned by repeating a photolithography process multiple times. Thereafter, the semiconductor pattern, conductive pattern, and signal line included in the circuit layer DP-CL may be complete.

In the case where the base layer BS is a silicon wafer, the circuit layer DP-CL may be formed by performing a CMOS process on the silicon wafer. Here, the circuit layer DP-CL may include refined semiconductor patterns, conductive patterns, and the like, and may provide the display panel DP with structure sizes suitable for providing high-resolution images.

The display layer DP-ED may be arranged on the circuit layer DP-CL. The display layer DP-ED may include lower patterns LSP, light-emitting elements ED, a pixel defining layer PDL, and a capping layer CPL.

The lower patterns LSP may be directly on an insulating layer on an uppermost side of the circuit layer DP-CL. The lower patterns LSP may include first to third lower patterns LSP1 to LSP3 per pixel region, e.g., pixel region PXA of FIG. 3. The first to third lower patterns LSP1 to LSP3 may be spaced apart from each other in a direction perpendicular to the thickness direction DR3.

The first lower patterns LSP1 may be arranged overlapping or underlying the first pixel region PXA-1 described above with reference to FIG. 3. The second lower patterns LSP2 may be arranged overlapping or underlying the second pixel region PXA-2 described above with reference to FIG. 3. The third lower patterns LSP3 may be arranged overlapping or underlying the third pixel region PXA-3 described above with reference to FIG. 3.

The lower patterns LSP may include a conductive material. In the present embodiment, the lower patterns LSP may include a metal oxide. For example, the lower patterns LSP may include tungsten oxide (WOₓ) or molybdenum titanium oxide (MoTiOₓ).

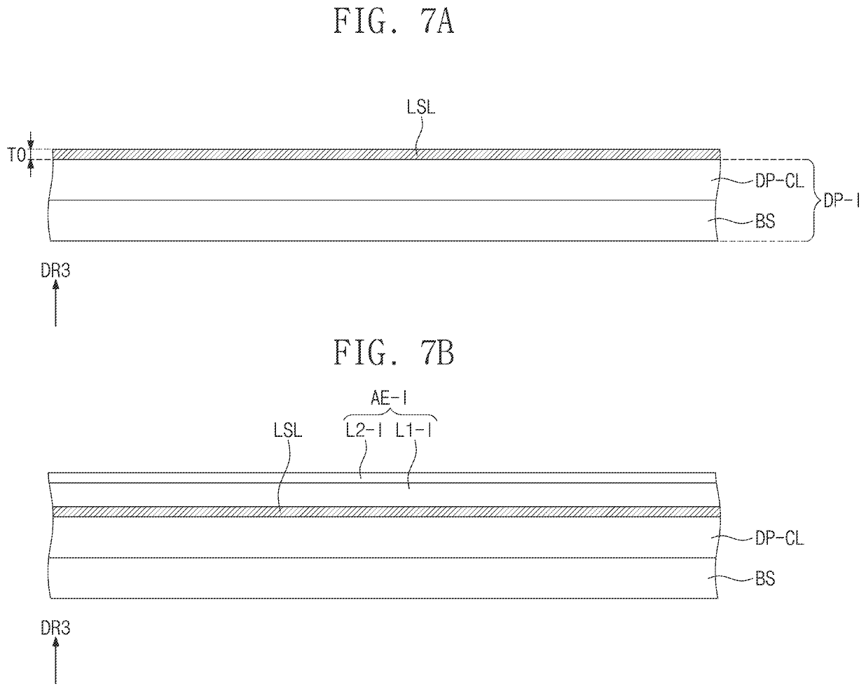

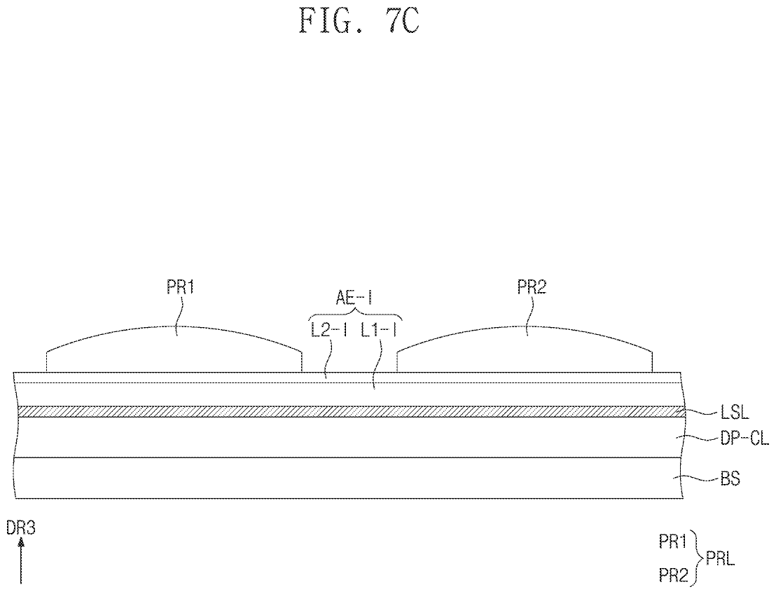

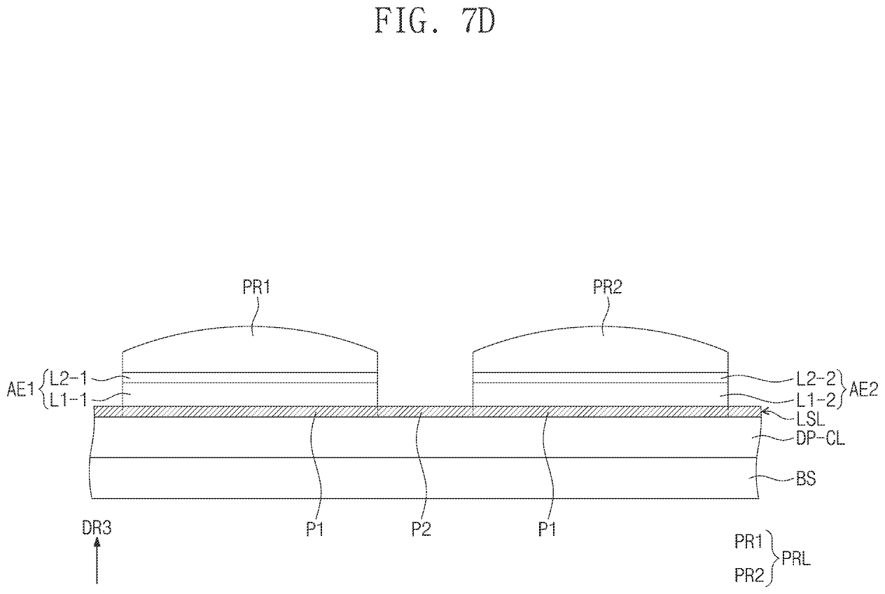

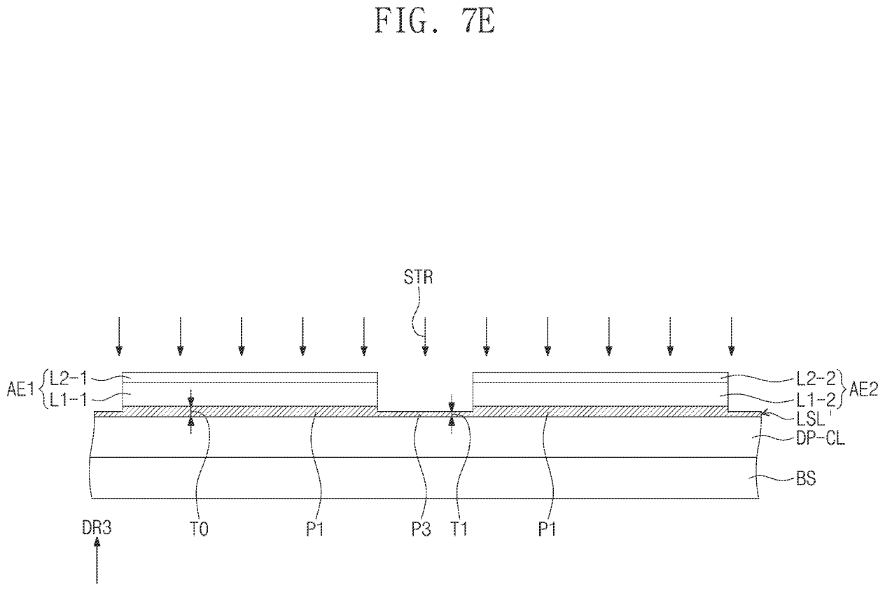

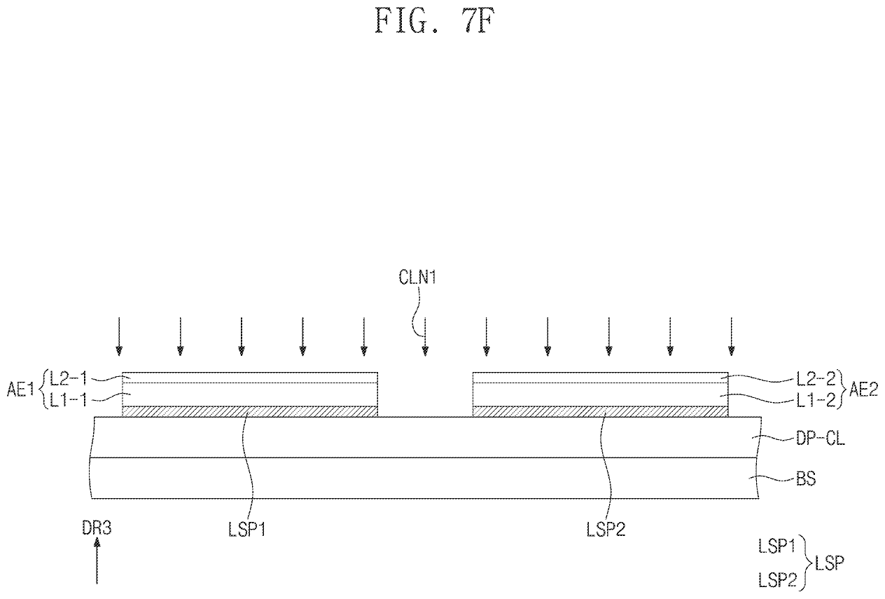

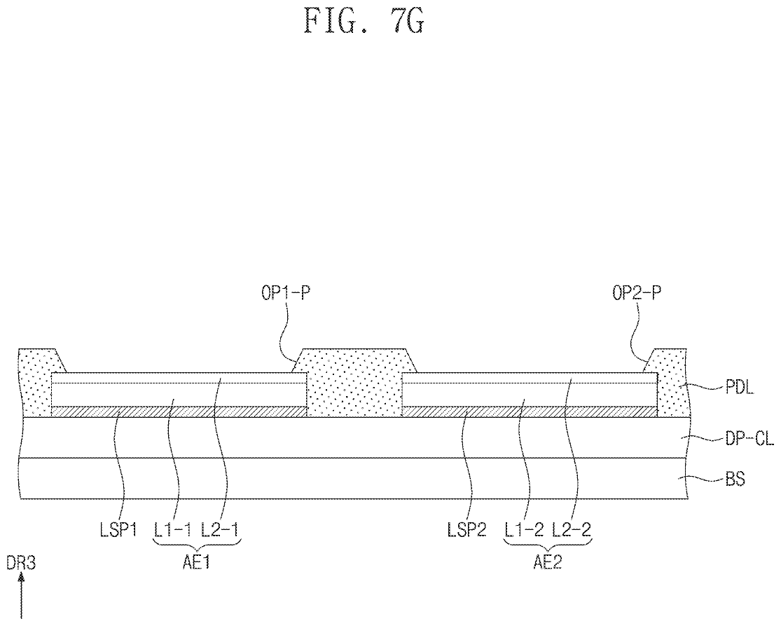

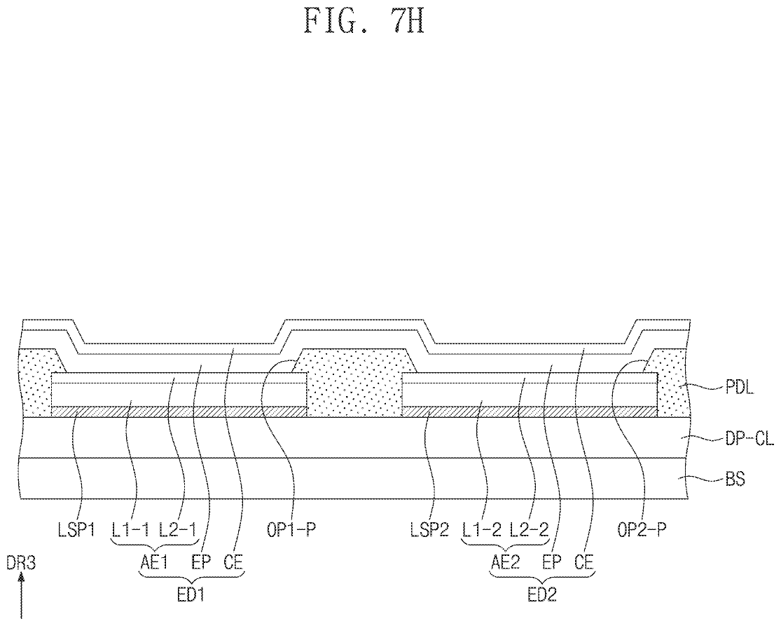

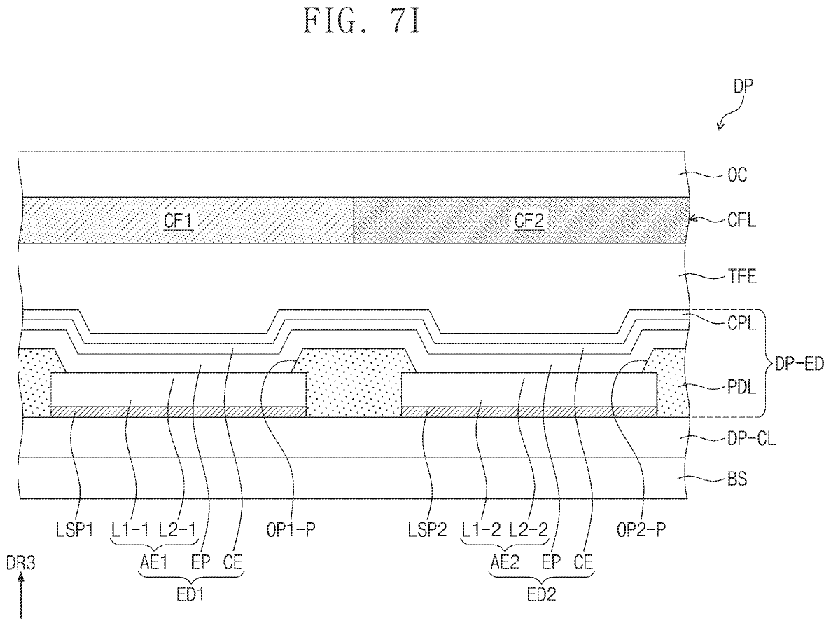

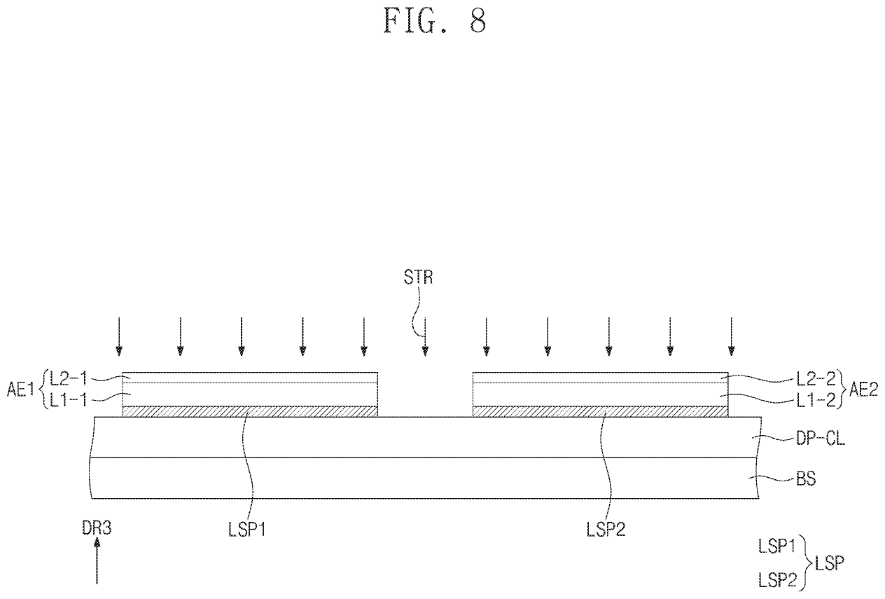

According to the present embodiment, the lower patterns LSP may be soluble in a strip solution or cleaning solution as described further below. Accordingly, in a patterning process for forming anodes AE1, AE2, and AE3 as described further below, patterning of a lower layer LSL (see FIG. 7A) may also be performed so as to form the lower patterns LSP.

A thickness of the lower patterns LSP may be set so that a portion of an initial deposition layer to be removed is sufficiently dissolved in a strip process or cleaning process that is described further below. The thickness of each of the lower patterns LSP may be about 10 nanometers or less. In more detail, the thickness of each of the lower patterns LSP may be about 5 nanometers or less. Further detailed descriptions are provided below.

The light-emitting elements ED may include first to third light-emitting elements ED1 to ED3 per pixel region, e.g., pixel region PXA of FIG. 3. The first to third light-emitting elements ED1 to ED3 may be spaced apart from each other in a direction perpendicular to the thickness direction DR3. The first to third light-emitting elements ED1 to ED3 each may include an anode AE1, AE2, or AE3 (or first electrode), an emission part EP, and a cathode CE (or second electrode) arranged on the emission part EP.

The anodes AE1 to AE3 of the first to third light-emitting elements ED1 to ED3 may be repeated in a pattern to form an array. The anodes AE1 to AE3 of FIG. 4 may include a first anode AE1 included in the first light-emitting element ED1, a second anode AE2 included in the second light-emitting element ED2, a third anode AE3 included in the third light-emitting element ED3.

The first anode AE1 may be directly on, overlapping, or overlying the first lower pattern LSP1. The second anode AE2 may be directly on, overlapping, or overlying the second lower pattern LSP2. The third anode AE3 may be directly on, overlapping, or overlying the third lower pattern LSP3. According to the present embodiment, by arranging the lower patterns LSP between the anodes AE1 to AE3 including a metal material and an insulating layer arranged on an uppermost side of the circuit layer DP-CL, enhanced adhesive strength may be provided between the anodes AE1 to AE3 and the circuit layer DP-CL through the lower patterns LSP.

An outer surface or edge of the first anode AE1 may be substantially aligned with an outer surface or edge of the first lower pattern LSP1. An outer surface or edge of the second anode AE2 may be substantially aligned with an outer surface or edge of the second lower pattern LSP2. An outer surface or edge of the third anode AE3 may be substantially aligned with an outer surface or edge of the third lower pattern LSP3.

The anodes AE1, AE2, and AE3 each may include a first layer L1-1, L1-2, or L1-3 and a second layer L2-1, L2-2, or L2-3 sequentially laminated along a direction (i.e., the third direction DR3) away from the base layer BS.

The first layers L1-1 to L1-3 may include a metal material. For example, the first layers L1-1 to L1-3 may include silver (Ag), magnesium (Mg), aluminum (Al), platinum (Pt), palladium (Pd), gold (Au), nickel (Ni), neodymium (Nd), iridium (Ir), chromium (Cr), or a compound thereof. The first layers L1-1 to L1-3 may be referred to as a “reflective layer”.

The second layers L2-1 to L2-3 may include a transparent conductive oxide (TCO). For example, the second layers L2-1 to L2-3 may include at least one material selected from the group consisting of indium tin oxide (ITO), indium zinc oxide (IZO), indium gallium zinc oxide (IGZO), zinc oxide (ZnO), indium oxide (In₂O₃), and aluminum doped zinc oxide (AZO). The second layers L2-1 to L2-3 may be referred to as a “transparent layer” or “translucent layer”. In an embodiment, the anodes AE1 to AE3 each may be a laminate structure including the first layer L1-1, L1-2, or L1-3 containing silver (Ag) and the second layer L2-1, L2-2, or L2-3 containing indium tin oxide (ITO).

In the present embodiment, the first layers L1-1 to L1-3 and the second layers L2-1 to L2-3 may have been patterned through a single etching process. Furthermore, as described above, since the lower patterns LSP are soluble in a strip solution or cleaning solution, the lower patterns LSP patterned from the lower layer LSL (see FIG. 7A) may be formed in a strip process or cleaning process following an etching process of the first layers L1-1 to L1-3 and the second layers L2-1 to L2-3. That is, the lower patterns LSP may be formed without performing an additional masking or etching process after the etching process for forming the first layers L1-1 to L1-3 and the second layers L2-1 to L2-3.

According to the present embodiment, since the anodes AE1 to AE3 and the lower patterns LSP may be formed by performing an etching process only one time, a process deviation (e.g., critical dimension (CD) skew) may be reduced. Furthermore, since an influence of isotropic etching is minimized, a degree to which a target material to be patterned is removed in a plane direction (i.e., a direction perpendicular to the third direction DR3) may be reduced. Accordingly, since the anodes AE1 to AE3 may be provided in a refined and precise pattern form, the display panel DP suitable for high resolution may be provided.

The pixel defining layer PDL may be on an insulating layer on an uppermost side of the circuit layer DP-CL and may be patterned to expose at least a portion of the anodes AE1 to AE3. In the pixel defining layer PDL, a first pixel opening OP1-P that exposes at least a portion of the first anode AE1, a second pixel opening OP2-P that exposes at least a portion of the second anode AE2, and a third pixel opening OP3-P that exposes at least a portion of the third anode AE3 may be defined.

The first pixel region PXA-1 may correspond to a portion of an upper surface of the first anode AE1, the portion being exposed from the pixel defining layer PDL through the first pixel opening OP1-P. The second pixel region PXA-2 may correspond to a portion of an upper surface of the second anode AE2, the portion being exposed from the pixel defining layer PDL through the second pixel opening OP2-P. The third pixel region PXA-3 may correspond to a portion of an upper surface of the third anode AE3, the portion being exposed from the pixel defining layer PDL through the third pixel opening OP3-P. That is, the first to third pixel regions PXA-1 to PXA-3 illustrated in FIG. 3 may respectively correspond to the first to third pixel openings OP1-P to OP3-P.

In an embodiment, the width W1 (see FIG. 3) of each of the first to third pixel openings OP1-P to OP3-P in the first direction DR1 (see FIG. 3) may be about 2 micrometers to about 8 micrometers, and the width W2 in the second direction DR2 may be about 2 micrometers to about 8 micrometers.

The non-pixel region NPXA is a region in the active region AA (see FIG. 2B) of the display panel DP excluding the first to third pixel regions PXA-1 to PXA-3. In the present disclosure, the first to third pixel regions PXA-1 to PXA-3 may be regions separated from each other by the pixel defining layer PDL. Namely, the pixel defining layer PDL may separate the light-emitting elements ED1 to ED3 by being arranged between the first to third anodes AE1 to AE3.

The pixel defining layer PDL may be an organic layer. For example, the pixel defining layer PDL may include general polymers such as benzocyclobutene (BCB), polyimide, hexamethyldisiloxane (HMDSO), polymethylmethacrylate (PMMA), or polystyrene (PS), or a polymer derivative having a phenol group, an acrylic polymer, an imidic polymer, an arylether polymer, an amidic polymer, a fluoric polymer, a p-xylene polymer, a vinyl alcohol polymer, and a blend thereof.

In an embodiment, the pixel defining layer PDL may have a property of absorbing light, and may have, for example, black color. The pixel defining layer PDL may include a black coloring agent. The black coloring agent may include a black dye or black pigment. The black coloring agent may include metals or other materials such as carbon black and chromium or oxides thereof. The pixel defining layer PDL may correspond to a light shielding pattern having a light shielding characteristic.

The emission part EP may be arranged on the anodes AE1 to AE3 and the pixel defining layer PDL. In the present embodiment, the emission part EP may be provided as a common layer for the first to third light-emitting elements ED1 to ED3. That is, the emission part EP may overlap or overlie all of the first to third pixel regions PXA-1 to PXA-3 and the non-pixel region NPXA and may be predominantly between the first to third anodes AE1 to AE3. The first to third light-emitting elements ED1 to ED3 may have a tandem arrangement. A laminate structure of the emission part EP is described below.

Meanwhile, in an embodiment of the present disclosure, the emission part EP may be provided in a form of patterns or regions arranged in the first to third pixel openings OP1-P to OP3-P respectively. That is, the emission part EP may include individual patterns for the first to third light-emitting elements ED1 to ED3. Here, the patterns of the emission part EP included in the first to third light-emitting elements ED1 to ED3 may differ to emit light of different colors.

The cathode CE may be arranged on the emission part EP. The cathode CE may be provided as a common layer for the first to third light-emitting elements ED1 to ED3. The cathode CE may overlap all of the first to third pixel regions PXA-1 to PXA-3 and the non-pixel region NPXA. That is, the cathode CE may be a common electrode.

The capping layer CPL may be on the cathode CE. The capping layer CPL may cover the light-emitting elements ED. The capping layer CPL may include an organic material.

The encapsulation layer TFE may be on the display layer DP-ED. The encapsulation layer TFE may include at least one inorganic film (hereinafter referred to as an inorganic encapsulation film). Furthermore, the encapsulation layer TFE may include at least one organic film (hereinafter referred to as an organic encapsulation film) and at least one inorganic encapsulation film.

The inorganic encapsulation film may protect the display layer DP-ED from moisture/oxygen, and the organic encapsulation film may protect the display layer DP-ED from foreign matter such as dust particles. The inorganic encapsulation film may include silicon nitride, silicon oxynitride, silicon oxide, titanium oxide, or aluminum oxide, but is not particularly limited thereto. The inorganic encapsulation film may include an acryl-based compound, epoxy-based compound, and the like. The organic encapsulation film may include a photopolymerizable organic material, but is not particularly limited.

The color filter layer CFL may be on the encapsulation layer TFE. The color filter layer CFL may include a first color filter CF1 corresponding to the first pixel region PXA-1, a second color filter CF2 corresponding to the second pixel region PXA-2, and a third color filter CF3 corresponding to the third pixel region PXA-3. Although not illustrated, the color filter layer CFL may further include a light shielding part (not shown). The light shielding part may be arranged in correspondence with the non-pixel region NPXA, or may be arranged in the non-pixel region NPXA so as to have a smaller width than the non-pixel region NPXA. The light shielding part may be a black matrix. The light shielding part may include an organic light-shielding material or inorganic light-shielding material including a black pigment or black dye. The light shielding part may prevent a light leakage phenomenon and may define boundaries between neighboring color filters CF1, CF2, and CF3. Meanwhile, in the present disclosure, the wording “region/portion corresponds to another region/portion” indicates that the regions/portions overlap, but is not limited to cases in which the regions/portions have the same area size.

The first to third color filters CF1 to CF3 each may include a polymeric photosensitive resin and a colorant. In the present disclosure, the colorant includes a pigment and dye. A red colorant may include a red pigment and red dye, a green colorant may include a green pigment and green dye, and a blue colorant may include a blue pigment and blue dye.

For example, the first color filter CF1 may include a red pigment or red dye, the second color filter CF2 may include a blue pigment or blue dye, and the third color filter CF3 may include a green pigment or green dye. Among beams of light provided from the emission part EP, light that has passed through the first color filter CF1 may provide red light to the outside of the display panel DP, light that has passed through the second color filter CF2 may provide blue light to the outside of the display panel DP, and light that has passed through the third color filter CF3 may provide green light to the outside of the display panel DP.

The planarization layer OC may be arranged on the color filter layer CFL. The planarization layer OC may cover the first to third color filters CF1 to CF3. The planarization layer OC may include an organic material. The organic material may be transparent and include, for example, an acryl-based resin. The planarization layer OC may provide a planar upper surface.

Meanwhile, according to the display panel according to an embodiment, the color filter layer and the planarization layer may not be provided.

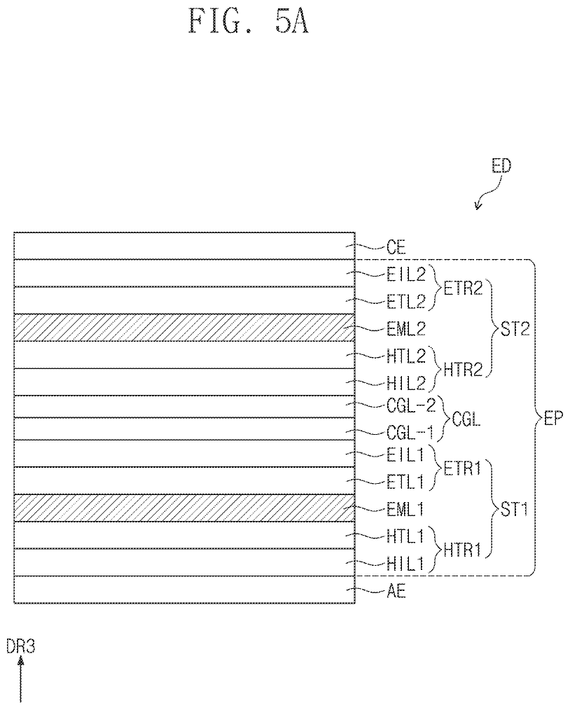

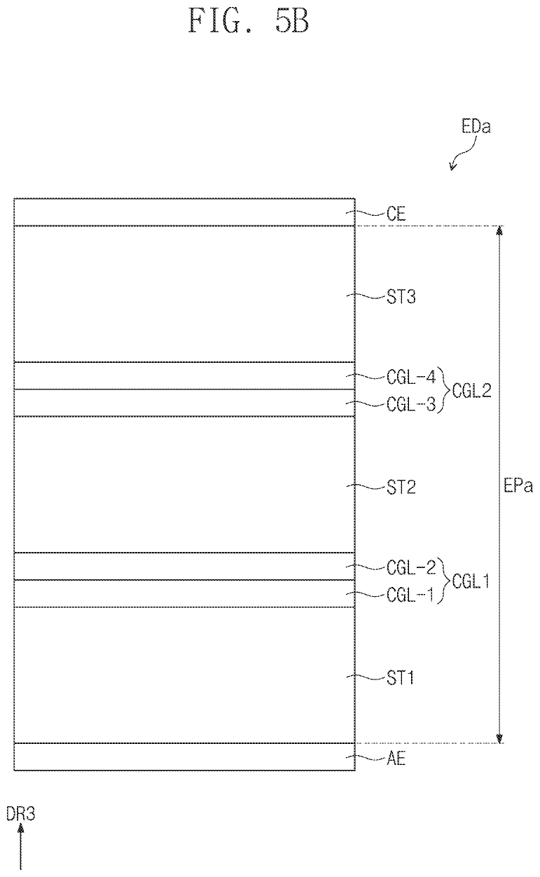

FIGS. 5A and 5B are enlarged cross-sectional views of portions of a light-emitting element according to an embodiment of the present disclosure.

Referring to FIG. 5A, the light-emitting element ED according to the present embodiment may include an anode AE, an emission part EP, and a cathode CE that are sequentially laminated in the third direction DR3. The light-emitting element ED of FIG. 5A may correspond to any one of the first to third light-emitting elements ED1 to ED3 described above with reference to FIG. 4, and the anode AE of FIG. 5A may correspond to any one of the first to third anodes AE1 to AE3 described above with reference to FIG. 4.

The emission part EP according to an embodiment of the present disclosure may include a first light-emitting stack ST1, a charge generation layer CGL, and a second light-emitting stack ST2 that are sequentially laminated in the third direction DR3. The light-emitting element ED may have a tandem structure including multiple light-emitting stacks ST1 and ST2.

The first light-emitting stack ST1 may include a first emission layer EML1 and a first hole control layer HTR1 and a first electron control layer ETR1 that are arranged with the first emission layer EML1 therebetween.

The first hole control layer HTR1 may include at least one of a first hole injection layer HIL1 or a first hole transport layer HTL1. The first hole transport layer HTL1 may include at least one of a first hole buffer layer or a first electron blocking layer.

The first electron control layer ETR1 may include at least one of a first electron injection layer EIL1 or a first electron transport layer ETL1. The first electron control layer ETR1 may further include a first hole blocking layer.

The second light-emitting stack ST2 may include a second emission layer EML2 and a second hole control layer HTR2 and a second electron control layer ETR2 that are arranged with the second emission layer EML2 therebetween.

The second hole control layer HTR2 may include at least one of a second hole injection layer HIL2 or a second hole transport layer HTL2. The second electron control layer ETR2 may include at least one of a second electron injection layer EIL2 or a second electron transport layer ETL2. The descriptions of the first hole control layer HTR1 and the first electron control layer ETR1 may also be applied to the second hole control layer HTR2 and the second electron control layer ETR2.

In an embodiment, beams of light respectively emitted from the light-emitting stacks ST1 and ST2 may have the same wavelength. For example, the light emitted from each of the light-emitting stacks ST1 and ST2 may be blue light. However, an embodiment of the present disclosure is not limited thereto, and the light-emitting stacks ST1 and ST2 may emit light of different wavelength regions. For example, at least one of the light-emitting stacks ST1 and ST2 may emit blue light and the other may emit green light. The light-emitting element ED including the light-emitting stacks ST1 and ST2 that emit light of different wavelength regions may emit white light.

The charge generation layer CGL may be arranged between the first light-emitting stack ST1 and the second light-emitting stack ST2. When a voltage is applied, the charge generation layer CGL may generate charges (electrons and holes) by forming complexes through oxidation-reduction reaction. Furthermore, the charge generation layer CGL may provide generated charges to each of the light-emitting stacks ST1 and ST2. The charge generation layer CGL may double efficiency of current generated in each of the light-emitting stacks ST1 and ST2, and may function to adjust balance of charges between the first light-emitting stack ST1 and the second light-emitting stack ST2.

In more detail, the charge generation layer CGL may have a layer structure in which a lower charge generation layer CGL-1 and an upper charge generation layer CGL-2 are bonded to each other. The lower charge generation layer CGL-1 may be an n-type charge generation layer arranged adjacent to the first light-emitting stack ST1 to provide electrons to the first light-emitting stack ST1. The lower charge generation layer CGL-1 may include an aryl amine-based organic compound.

The upper charge generation layer CGL-2 may be a p-type charge generation layer arranged adjacent to the second light-emitting stack ST2 to provide holes to the second light-emitting stack ST2. The upper charge generation layer CGL-2 may include metal, metal oxide, carbide, fluoride, or a charge generating compound composed of a mixture thereof.

A buffer layer may be further arranged between the lower charge generation layer CGL-1 and the upper charge generation layer CGL-2.

According to the present embodiment, the first light-emitting stack ST1, the charge generation layer CGL, and the second light-emitting stack ST2 may be formed commonly across multiple pixels or an entire array of pixels using an open mask. However, an embodiment of the present disclosure is not limited thereto, and at least one of the first and second hole control layers HTR1 and HTR2, the first and second emission layers EML1 and EML2, or the first and second electron control layers ETR1 and ETR2 may be formed by being patterned through a mask. For example, each of the first and second emission layers EML1 and EML2 may be arranged in a region corresponding to the pixel openings OP1-P, OP2-P, and OP3-P (see FIG. 4). That is, the first and second emission layers EML1 and EML2 may be separately formed in each of pixels.

Referring to an emission element EDa shown in FIG. 5B, an emission part EPa according to an embodiment of the present disclosure may include a first light-emitting stack ST1, a first charge generation layer CGL1, a second light-emitting stack ST2, a second charge generation layer CGL2, and a third light-emitting stack ST3. That is, in the present embodiment, the emission part EPa may include three light-emitting stacks ST1 to ST3 and two charge generation layers CGL1 and CGL2 arranged between adjacent light-emitting stacks ST1 to ST3. The same/similar reference signs are used for the same/similar components described with reference to FIG. 5A, and overlapping descriptions are not repeated here.

The third light-emitting stack ST3 may have a structure similar to the first and second light-emitting stacks ST1 and ST2 described above with reference to FIG. 5A. The third light-emitting stack ST3 may include a third hole control layer, a third emission layer, and a third electron control layer that are sequentially laminated on the second charge generation layer ETR2 (see FIG. 5A) in the third direction DR3.

Furthermore, the first and second charge generation layers CGL1 and CGL2 each may have a structure similar to the charge generation layer CGL described above with reference to FIG. 5A. The first charge generation layer CGL1 may have a layer structure in which a first lower charge generation layer CGL-1 and a first upper charge generation layer CGL-2 are bonded to each other, and the second charge generation layer CGL2 may have a layer structure in which a second lower charge generation layer CGL-3 and a second upper charge generation layer CGL-4 are bonded to each other.

Meanwhile, the number of the light-emitting stacks ST1 to ST3 and the number of the charge generation layers CGL1 and CGL2 are not limited to the illustrations of FIGS. 5A and 5B, and four or more light-emitting stacks and three or more charge generation layers arranged therebetween may be included.

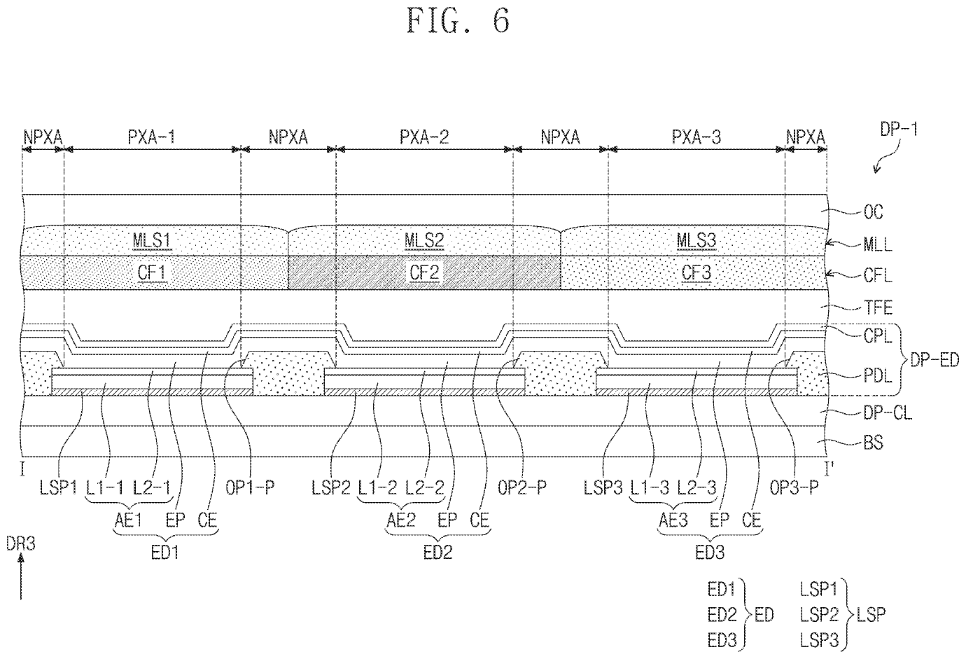

FIG. 6 is a cross-sectional view of the display panel according to an embodiment taken along line I-I′ of FIG. 3.

Referring to FIG. 6, a display panel DP-1 according to the present embodiment may include the base layer BS, the circuit layer DP-CL, the display layer DP-ED, the encapsulation layer TFE, the color filter layer CFL, a lens layer MLL, and the planarization layer OC. Compared to the embodiment described above with reference to FIG. 4, the display panel DP-1 according to the present embodiment may further include the lens layer MLL arranged between the color filter layer CFL and the planarization layer OC. The same/similar reference signs are used for the same/similar components described with reference to FIG. 4, and overlapping descriptions will not be repeated here.

The lens layer MLL may include a first mounted lens MLS1 corresponding to the first pixel region PXA-1, a second mounted lens MLS2 corresponding to the second pixel region PXA-2, and a third mounted lens MLS3 corresponding to the third pixel region PXA-3. The first to third mounted lenses MLS1 to MLS3 each may be a convex lens. The first to third mounted lenses MLS1 to MLS3 may concentrate beams of light provided from the first to third color filters CF1 to CF3 so as to improve efficiency of light emission. The first to third mounted lenses MLS1 to MLS3 may be micro lenses.

FIGS. 7A to 7H are cross-sectional views illustrating some operations of a display panel manufacturing method according to an embodiment of the present disclosure. In order to describe the display panel manufacturing method with reference to FIGS. 7A to 7H, the same/similar reference signs are used for the same/similar components described above with reference to FIGS. 1 to 6, and overlapping descriptions will not be repeated here.

The display panel manufacturing method according to an embodiment of the present disclosure includes forming a lower layer on a base layer, forming a preliminary anode including a first initial layer and a second initial layer sequentially laminated on the lower layer, patterning the preliminary anode so as to form an anode including a first layer and a second layer, forming an emission part on the anode, and forming a cathode on the emission part, wherein the patterning of the preliminary anode includes forming a photoresist layer on the second initial layer, etching the first and second initial layers so as to form the first and second layers respectively from the first initial layer and the second initial layer, removing the photoresist layer, and first cleaning. The lower layer includes a first portion overlapping the anode and a second portion exposed from the anode, and at least a part of the second portion is removed during at least one of the removing of the photoresist layer and the first cleaning.

Referring to FIG. 7A, the display panel manufacturing method according to the present embodiment may include forming the lower layer LSL on the base layer BS.

In detail, the lower layer LSL may be formed on a preliminary display panel DP-I. In the present embodiment, the preliminary display panel DP-I may include the base layer BS and the circuit layer DP-CL arranged on the base layer BS. The circuit layer DP-CL may be formed through a typical circuit element manufacturing process in which an insulating layer, a semiconductor layer, and a conductive layer are formed through coating, deposition, or the like, and a semiconductor pattern, a conductive pattern, and a signal line are formed by selectively patterning the insulating layer, the semiconductor layer, and the conductive layer through photolithography and etching.

The lower layer LSL may be formed by being deposited on an insulating layer on an uppermost side of the circuit layer DP-CL. For example, the lower layer LSL may be deposited through a sputtering process. The lower layer LSL may include a conductive material. In the present embodiment, the lower layer LSL may include a metal oxide. For example, the lower layer LSL may include tungsten oxide (WOₓ) or molybdenum titanium oxide (MoTiOₓ).

In the present embodiment, the lower layer LSL may be formed to a thickness of about 10 nanometers or less. More specifically, the thickness of the lower layer LSL may be about 5 nanometers or less. In the case where the lower layer LSL has a thickness of about 10 nanometers or less, the lower layer LSL may be partially removed while a preliminary anode AE-I (see FIG. 7B) that is described below is being patterned, and thus lower patterns LSP (see FIG. 7F) having a form of patterns may be formed from the lower layer LSL. Relevant detailed descriptions is provided below.

Referring to FIG. 7B, the display panel manufacturing method according to the present embodiment may include forming the preliminary anode AE-I on the lower layer LSL.

The preliminary anode AE-I may include a first initial layer L1-I and a second initial layer L2-I sequentially laminated on the lower layer LSL in a direction away from the lower layer LSL. The preliminary anode AE-I may be formed by depositing the first initial layer L1-I on the lower layer LSL and depositing the second initial layer L2-I on the first initial layer L1-I. For example, the first initial layer L1-I and the second initial layer L2-I each may be formed through a sputtering process.

The first initial layer L1-I may include a metal material. For example, the first initial layer L1-I may include silver (Ag), magnesium (Mg), aluminum (Al), platinum (Pt), palladium (Pd), gold (Au), nickel (Ni), neodymium (Nd), iridium (Ir), chromium (Cr), or a compound thereof. The second initial layer L2-I may include a transparent conductive oxide (TCO). For example, the second initial layer L2-I may include at least one material selected from the group consisting of indium tin oxide (ITO), indium zinc oxide (IZO), indium gallium zinc oxide (IGZO), zinc oxide (ZnO), indium oxide (In₂O_{I40}), and aluminum doped zinc oxide (AZO). In an embodiment, the preliminary anode AE-I uses a combination of the first initial layer L1-I containing silver (Ag) and the second initial layer L2-I containing indium tin oxide (ITO).

Referring to FIGS. 7C to 7F, the display panel manufacturing method according to the present embodiment may include patterning the preliminary anode AE-I so as to form the anodes AE1 and AE2.

In the present embodiment, the patterning of the preliminary anode AE-I may include forming a photoresist layer PRL, etching the first and second initial layers L1-I and L2-I where exposed by the photoresist layer PRL, removing the photoresist layer PRL, and first cleaning.

Referring to FIG. 7C, the patterning of the preliminary anode AE-I may include forming the photoresist layer PRL on the preliminary anode AE-I.

The photoresist layer PRL may include a plurality of photoresist patterns or regions PR1 and PR2 that are spaced apart from each other. Although FIG. 7C illustrates two photoresist patterns PR1 and PR2 (hereinafter referred to as a first photoresist pattern PR1 and a second photoresist pattern PR2) spaced apart from each other, the photoresist patterns PR1 and PR2 may cover separated areas of the preliminary anode AE-I that respectively correspond to the anodes AE1 and AE2 (see FIG. 7D) to be formed using the photoresist patterns PR1 and PR2 as an etch mask.

The first photoresist pattern PR1 and the second photoresist pattern PR2 each may be formed by depositing a preliminary photoresist layer on the second initial layer L2-I and patterning the preliminary photoresist layer using a photomask.

Thereafter, referring to FIGS. 7C and 7D, the patterning of the preliminary anode AE-I may include etching the first and second initial layers L1-I and L2-I so as to form first layers L1-1 and L1-2 and second layers L2-1 and L2-2 from the first initial layer L1-I and the second initial layer L2-I.

The photoresist layer PRL may be used as a mask in an etching process of the first and second initial layers L1-I and L2-I. Accordingly, the first layers L1-1 and L1-2 respectively corresponding to the first and second photoresist patterns PR1 and PR2 may be formed. Furthermore, the second layers L2-1 and L2-2 respectively corresponding to the first and second photoresist patterns PR1 and PR2 may be formed. That is, the first layers L1-1 and L1-2 and the second layers L2-1 and L2-2 may be provided in a form of patterns corresponding to the photoresist patterns PR1 and PR2 through a patterning process. In this manner, the first anode AE1 and the second anode AE2 each including the first layer L1-1 or L1-2 and the second layer L2-1 or L2-2 may be formed.

Although FIG. 7D exemplarily illustrates only the first and second anodes AE1 and AE2, the third anode AE3 described above with reference to FIG. 4 may also be formed through an etching process of the first and second initial layers L1-I and L2-I.

In the present embodiment, the etching process of the first and second initial layers L1-I and L2-I may be carried out as a wet etching process. The etching process of the present embodiment may be carried out in an etching environment in which each of the first and second initial layers L1-I and L2-I have substantially the same etch rate. Accordingly, outer surfaces or edges of the first layer L1-1 and the second layer L2-1 constituting the first anode AE1 may be substantially aligned, and outer surfaces or edges of the first layer L1-2 and the second layer L2-2 constituting the second anode AE2 may be substantially aligned. Meanwhile, in the present disclosure, the wording “outer surfaces are substantially aligned” may include the case where an error occurs in an etching process and may also include the case where partially ununiform outer surfaces are formed.

The lower layer LSL may include a first portion P1 overlapping and underlying the anodes AE1 and AE2 and a second portion P2 exposed from the anodes AE1 and AE2. The first portion P1 may include multiple separated regions or portions P1, and the first portions P1 may correspond to portions respectively overlapping or underlying the anodes AE1 and AE2. The second portion P2 may correspond to a region of the lower layer LSL excluding the first portions P1.

Thereafter, referring to FIGS. 7D and 7E, the patterning of the preliminary anode AE-I (see FIG. 7C) may include removing the photoresist layer PRL (or a strip process).

A first solution STR may be injected onto the photoresist layer PRL and the portions P2 of the lower layer LSL during the removing of the photoresist layer PRL. The first solution STR may be referred to as a strip solution STR. For example, the first solution STR may be a solution in which sulfuric acid (H₂SO₄) and hydrogen peroxide (H₂O₂) are mixed at a certain ratio. Alternatively, the first solution STR may be tetramethyl ammonium hydroxide (TMAH).

According to the present embodiment, the lower layers LSL and LSL′ may be soluble in the first solution (i.e., strip solution STR). Accordingly, at least a part of the second portion P2 of the lower layer LSL may be removed during the removing of the photoresist layer PRL.

FIGS. 7D and 7E illustrate an example in which the second portion P2 is partially removed during the removing of the photoresist layer PRL. Here, a third portion P3 that is thinner than the second portion P2 may be formed from the second portion P2, and the lower layer LSL′ including the first portion P1 and the third portion P3 may be formed. As illustrated in FIG. 7E, immediately after completing the removing of the photoresist layer PRL, a thickness T1 of the third portion P3 may be smaller than a thickness TO of the first portion P1.

Thereafter, referring to FIGS. 7E and 7F, the patterning of the preliminary anode AE-I (see FIG. 7C) may include first cleaning.

A second solution CLN1 may be injected during the first cleaning. The second solution CLN1 may be referred to as a first cleaning solution CLN1. For example, the second solution CLN1 may be deionized (DI) water. Through the first cleaning, residues remaining on the anodes AE1 and AE2 and the lower layer LSL′ may be removed after the etching process of the first and second initial layers L1-I and L2-I (see FIG. 7C) and the removing process of the photoresist layer PRL (see FIG. 7D).

According to the present embodiment, the lower layer LSL′ may be soluble in the second solution CLN1 (i.e., first cleaning solution CLN1). Accordingly, when a portion of the lower layer LSL′ exposed from the anodes AE1 and AE2 partially remains immediately after completing the removing of the photoresist layer PRL, the remaining portion of the lower layer LSL′ exposed from the anodes AE1 and AE2 may be entirely removed during the first cleaning. In detail, when the lower layer LSL′ includes the third portion P3 exposed from the anodes AE1 and AE2 immediately after completing the removing of the photoresist layer PRL, the first cleaning may entirely remove the third portion P3. In this manner, the lower patterns LSP spaced apart from the lower layer LSL′ may be formed. The lower patterns LSP may respectively correspond to the first portions P1 of the lower layers LSL and LSL′ (see FIG. 7D). The first lower pattern LSP1 arranged under the first anode AE1 and the second lower pattern LSP2 arranged under the second anode AE2 may be formed.

That is, according to an embodiment of the present disclosure, the lower patterns LSP1 and LSP2 arranged under the anodes AE1 and AE2 may be formed through subsequent processes following the etching process of the preliminary anode AE-I (see FIG. 7C) for forming the anodes AE1 and AE2. Accordingly, the lower patterns LSP1 and LSP2 may be formed without performing an additional etching process before or after the patterning process of the preliminary anode AE-I (see FIG. 7C). Therefore, since all of the anodes AE1 and AE2 and the lower patterns LSP1 and LSP2 may be formed by performing an etching process one time, a manufacturing process may be simplified, and the anodes AE1 and AE2 may be formed with a reduced process error (e.g., CD skew).

Furthermore, since an etching process is performed only one time while forming the anodes AE1 and AE2, intentional over etching may not be performed or needed in order to handle a process error so as to ensure patterning of the anodes AE1 and AE2. In particular, since wet etching may be performed in an isotropic manner, the etching may also progress in a plane direction (i.e., direction perpendicular to the third direction DR3), and the degree of the etching in the plane direction may increase as an etching process time increases. According to an embodiment of the present disclosure, since an etching process is not performed multiple times, the degree of intentional over etching may be reduced or over etching may not be performed intentionally. Accordingly, since the degree of etching in a plane direction may be minimized, refined or precise patterns may be easily formed. For example, microscale patterns may be formed so that microscale pixel regions PXA-1 to PXA-3 (see FIG. 3) may be provided. Therefore, the display panel DP (see FIG. 7I) suitable for high resolution may be manufactured.

The first cleaning described above may be performed for about 30 seconds to about 120 seconds. That is, the lower layer LSL′ may be exposed to the first cleaning solution CLN1 for about 30 seconds to about 120 seconds. The lower layer LSL′ may be dissolved by as much as a thickness of about 4 nanometers to about nanometers per minute with regard to the first cleaning solution CLN1. Accordingly, during the forming of the lower layer LSL described above with reference to FIG. 7A, when the lower layer LSL having a thickness of about 10 nanometers or less is provided, a portion of the lower layer LSL′ exposed from the anodes AE1 and AE2 may be sufficiently removed, thereby forming the lower patterns LSP. In more detail, the first cleaning may be performed for about 60 seconds, and, in this case, the lower layer LSL having a thickness of about 5 nanometers or less may be provided during the forming of the lower layer LSL described above with reference to FIG. 7A.

Meanwhile, according to an embodiment of the present disclosure, a second portion of the lower layer may not be removed during the removing of the photoresist layer but may be entirely removed during the first cleaning.

Thereafter, as illustrated in FIG. 7G, the display panel manufacturing method according to an embodiment of the present disclosure may include forming the pixel defining layer PDL. The pixel defining layer PDL may be arranged on an insulating layer arranged on an uppermost side of the circuit layer DP-CL and may expose at least a portion of the anodes AE1 and AE2. In the pixel defining layer PDL, the first pixel opening OP1-P that exposes a portion of the first anode AE1 and the second pixel opening OP2-P that exposes a portion of the second anode AE2 may be defined.

In an embodiment, the pixel defining layer PDL may be formed, in which the pixel openings OP1-P and OP2-P respectively overlapping and overlying the anodes AE1 and AE2 are formed, through deposition, photolithography, and etching processes. However, an embodiment is not limited thereto.

Thereafter, as illustrated in FIG. 7H, the display panel manufacturing method according to an embodiment of the present disclosure may include forming the emission part EP and forming the cathode CE.

The emission part EP may be formed on the anodes AE1 and AE2 and the pixel defining layer PDL. The cathode CE may be formed on the emission part EP. The first anode AE1, the emission part EP, and the cathode CE may provide the first light-emitting element ED1, and the second anode AE2, the emission part EP, and the cathode CE may provide the second light-emitting element ED2. FIG. 7H exemplarily illustrates that the emission part EP is provided as a common layer for the light-emitting elements ED1 and ED2, but an embodiment is not limited thereto, and the emission part EP may be provided as individual patterns or regions respectively for the light-emitting elements ED1 and ED2.

FIG. 7H exemplarily illustrates only the first light-emitting element ED1 and the second light-emitting element ED2, and, as described above with reference to FIG. 4, the third light-emitting element ED3 including the third anode AE3, the emission part EP, and the cathode CE may be further provided.

In an embodiment, the emission part EP and the cathode CE each may be formed through a deposition process. However, an embodiment is not limited thereto.

Thereafter, referring to FIG. 7I, the display panel manufacturing method according to the present embodiment may include forming the capping layer CPL on the cathode CE, forming the encapsulation layer TFE on the capping layer CPL, forming the color filter layer CFL on the encapsulation layer TFE, and forming the planarization layer OC on the color filter layer CFL. In this manner, the display panel DP including the base layer BS, the circuit layer DP-CL, the display layer DP-ED, the encapsulation layer TFE, the color filter layer CFL, and the planarization layer OC may be formed. This panel may correspond to the display panel DP described above with reference to FIG. 4.

The color filter layer CFL may include the color filters CF1 and CF2 respectively overlapping or overlying the anodes AE1 and AE2. FIG. 7I exemplarily illustrates only the first color filter CF1 of the color filter layer CFL overlapping the first anode AE1 and the second color filter CF2 overlapping the second anode AE2, and, as described above with reference to FIG. 4, the color filter layer CFL may further include the third color filter CF3 overlapping the third anode AE3.

According to an embodiment, the method may further include forming the lens layer MLL (see FIG. 6) between the forming of the color filter layer CFL and the forming of the planarization layer OC. In this manner, the display panel DP-1 including the base layer BS, the circuit layer DP-CL, the display layer DP-ED, the encapsulation layer TFE, the color filter layer CFL, the lens layer MLL (see FIG. 6) and the planarization layer OC may be formed, and this panel may correspond to the display panel DP-1 described above with reference to FIG. 6.

Meanwhile, according to the display panel manufacturing method according to an embodiment, the forming of the capping layer may be skipped. Alternatively, according to the display panel manufacturing method according to an embodiment, the forming of the color filter layer and the forming of the planarization layer may be skipped.

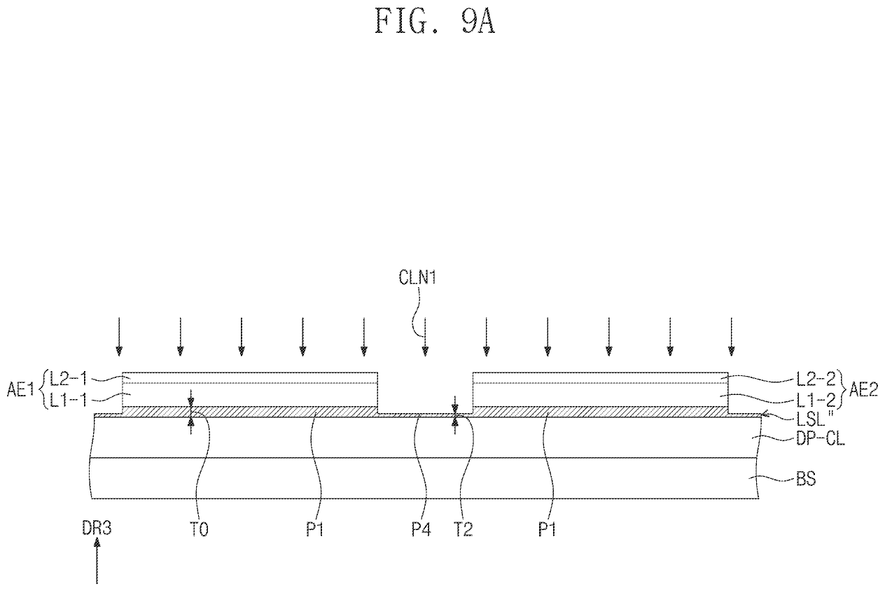

FIG. 8 is a cross-sectional view illustrating some operations of a display panel manufacturing method according to an embodiment. FIG. 8 illustrates removal of the photoresist layer PRL (see FIG. 7D) performed during the patterning of the preliminary anode AE-I (see FIG. 7C) in the display panel manufacturing method described above with reference to FIGS. 7A to 7I. The same/similar reference signs are used for the same/similar components described with reference to FIGS. 7A to 7I, and overlapping descriptions are not repeated here.

Referring to FIGS. 7D and 8, during the removing of the photoresist layer PRL according to the present embodiment, a portion of the lower layer LSL exposed from the anodes AE1 and AE2 may be entirely removed. Accordingly, in the present embodiment, during the removing of the photoresist layer PRL, the lower patterns LSP1 and LSP2 spaced apart from each other may be formed from the lower layer LSL.

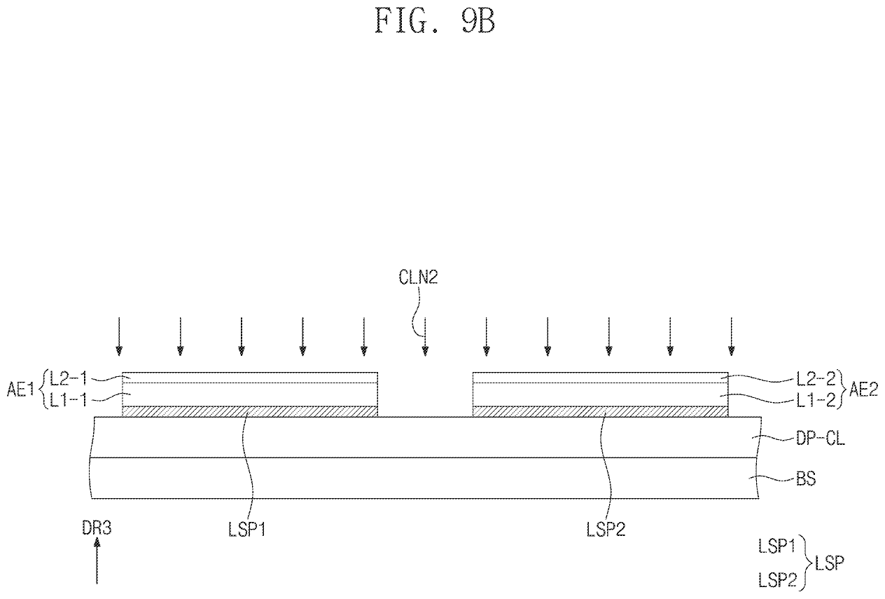

FIGS. 9A and 9B are cross-sectional views illustrating some operations of a display panel manufacturing method according to an embodiment of the present disclosure.

The display panel manufacturing method according to the present embodiment may further include second cleaning before the forming of the pixel defining layer PDL (see FIG. 7G) after the patterning of the preliminary anode AE-I (see FIGS. 7C to 7F). FIG. 9A illustrates the first cleaning performed during the patterning of the preliminary anode in the display panel manufacturing method, and FIG. 9B illustrates the second cleaning in the display panel manufacturing method.

Referring to FIGS. 7E and 9A, during the first cleaning according to the present embodiment, only a part of the third portion P3 of the lower layer LSL′ may be removed. Here, a fourth portion P4 that is thinner than the third portion P3 may be formed from the third portion P3, and a lower layer LSL″ including the first portion P1 and the fourth portion P4 may be formed. As illustrated in FIG. 9A, immediately after completing the first cleaning, a thickness T2 of the fourth portion P4 may be smaller than the thickness TO of the first portion P1.

Thereafter, referring to FIGS. 9A, 9B, and 7G, the second cleaning according to the present embodiment may be performed immediately before performing the forming of the pixel defining layer PDL. Through the second cleaning, a clean surface may be provided to the pixel defining layer PDL by removing foreign matter, formed due to process, on an upper surface of an insulating layer arranged on an uppermost side of the circuit layer DP-CL and upper surfaces of the anodes AE1 and AE2.

A third solution CLN2 may be injected onto a top surface during the second cleaning. The third solution CLN2 may be referred to as a second cleaning solution CLN2. The second cleaning solution CLN2 may be the same as or different from the first cleaning solution CLN1.

According to the present embodiment, even if a portion of the lower layer LSL″ exposed from the anodes AE1 and AE2 partially remains after completing the first cleaning, the remaining portion of the lower layer LSL″ exposed from the anodes AE1 and AE2 may be entirely removed during the second cleaning. In detail, when the lower layer LSL″ includes the fourth portion P4 exposed from the anodes AE1 and AE2 immediately after completing the first cleaning, the fourth portion P4 may be entirely removed during the second cleaning. Accordingly, in the present embodiment, during the second cleaning for providing a clean surface to the pixel defining layer PDL, the lower patterns LSP spaced apart from each other may be formed from the lower layer LSL″. The lower patterns LSP may respectively correspond to the first portions P1 of the lower layers LSL, LSL′, and LSL″ (see FIGS. 7D and 7E).

According to an embodiment of the present disclosure, since a lower pattern arranged under an anode is included, the anode may be formed through an etching process performed one time. Furthermore, the lower pattern may be patterned through a strip process and cleaning process following an anode etching process without performing an additional etching process. In this manner, when performing the anode etching process, intentional over etching may be avoided, and thus a process error (e.g., CD skew) of the anode may be reduced. A display panel suitable for high resolution and a method of manufacturing the same may be provided.

Although the embodiments of the present invention have been described, it is understood that the present invention should not be limited to these embodiments, but various changes and modifications can be made by one ordinary skilled in the art within the spirit and scope of the present invention as hereinafter claimed.

What is claimed is:

1. A method of manufacturing a display panel, the method comprising:
forming a lower layer on a base layer;
forming a preliminary anode including a first initial layer and a second initial layer sequentially laminated on the lower layer;
patterning the preliminary anode so as to form an anode including a first layer and a second layer;
forming an emission part on the anode; and
forming a cathode on the emission part,
wherein the patterning of the preliminary anode includes:
forming a photoresist layer on the second initial layer;
etching the first and second initial layers so as to form the first layer and the second layer respectively from the first initial layer and the second initial layer;
removing the photoresist layer; and
first cleaning,
wherein the lower layer includes a first portion overlapping the anode and a second portion exposed from the anode, and
at least a part of the second portion is removed during at least one of the removing of the photoresist layer or the first cleaning.

2. The method of claim 1, wherein a strip solution is used in the removing of the photoresist layer, and the lower layer is soluble in the strip solution.

3. The method of claim 1, wherein a first cleaning solution is used in the first cleaning, and the lower layer is soluble in the first cleaning solution.

4. The method of claim 3, wherein the first cleaning solution includes deionized (DI) water.

5. The method of claim 1, wherein the first cleaning is performed for about 30 seconds to about 120 seconds.

6. The method of claim 1, wherein
the lower layer includes any one of tungsten oxide and molybdenum titanium oxide,
the first initial layer includes metal, and
the second initial layer includes a transparent conductive oxide.

7. The method of claim 1, wherein a thickness of the lower layer is about nanometers or less.

8. The method of claim 1,
wherein the second portion is entirely removed during one of the removing of the photoresist layer or the first cleaning, thus forming a lower pattern from the lower layer, and
wherein the lower pattern corresponds to the first portion.

9. The method of claim 1, wherein
a part of the second portion is removed during the removing of the photoresist layer, thus forming a third portion that is thinner than the second portion,
the third portion is entirely removed during the first cleaning, thus forming a lower pattern from the lower layer, and
the lower pattern corresponds to the first portion.

10. The method of claim 1, further comprising, before the forming of the emission part and after the patterning of the preliminary anode:
second cleaning; and
forming a pixel defining layer that defines a pixel opening exposing at least a portion of the anode, wherein
a part of the second portion is removed during the patterning of the preliminary anode, thus forming a fourth portion that is thinner than the second portion,
the fourth portion is entirely removed during the second cleaning, thus forming a lower pattern from the lower layer, and
the lower pattern corresponds to the first portion.

11. The method of claim 10, wherein a width of the pixel opening in one direction is about 2 micrometers to about 8 micrometers.

12. The method of claim 1, wherein the base layer includes a silicon wafer.

13. The method of claim 1, further comprising, after the forming of the cathode:
forming an encapsulation layer on the cathode; and
forming, on the encapsulation layer, a color filter layer including a first color filter overlapping the first anode and a second color filter overlapping the second anode.

14. The method of claim 13, further comprising forming a lens layer including a first mounted lens arranged on the first color filter and a second mounted lens arranged on the second color filter.

15. A display panel comprising:
a base layer including a silicon wafer;
a first lower pattern on the base layer;
a first anode including a first layer and a second layer sequentially laminated on the first lower pattern;
a pixel defining layer arranged on the base layer and having defined therein a first pixel opening that exposes at least a portion of the first anode;
an emission part on the first anode; and
a cathode on the emission part,
wherein the first lower pattern includes a metal oxide, and
a thickness of the first lower pattern is about 10 nanometers or less.

16. The display panel of claim 15, wherein a width of the first pixel opening in one direction is about 2 micrometers to about 8 micrometers.

17. The display panel of claim 15, wherein the first lower pattern includes any one of tungsten oxide and molybdenum titanium oxide.

18. The display panel of claim 15, further comprising:
a second lower pattern arranged on the base layer and spaced apart from the first lower pattern;
a second anode arranged on the second lower pattern and spaced apart from the first anode;
a color filter layer arranged on the cathode and including a first color filter overlapping the first anode and a second color filter overlapping the second anode; and
a planarization layer on the color filter layer.

19. The display panel of claim 18, wherein the emission part includes on the first anode and the second anode, a plurality of light-emitting stacks and at least one charge generation layer between the light-emitting stacks.

20. The display panel of claim 18, further comprising a lens layer arranged between the color filter layer and the planarization layer and including a first lens overlapping the first anode and a second lens overlapping the second anode.
